(19) United States
(12) Patent Application Publication
(10) Pub. No.: US 2026/0011571 A1
(43) Pub. Date: Jan. 8, 2026

(54) SELECTIVE MATERIAL DEPOSITION

(71) Applicant: Applied Materials, Inc., Santa Clara, CA (US)

(72) Inventors: Yi YANG, San Jose, CA (US); Sean S. KANG, San Ramon, CA (US); Srinivas D. NEMANI, Sunnyvale, CA (US); Ellie Y. YIEH, San Jose, CA (US)

(21) Appl. No.: 18/762,834

(22) Filed: Jul. 3, 2024

(51) Int. Cl. H01L 21/3205; C23C 16/455; C23C 16/52; H01L 21/3213; H01L 21/66

(52) U.S. Cl. CPC H01L 21/32053; C23C 16/45538; C23C 16/52; H01L 21/32138; H01L 22/26

(57) ABSTRACT

Methods and apparatus for depositing a metal containing-layer in a semiconductor processing chamber. One example method generally includes delivering a processing gas into the semiconductor processing chamber during a time period, where the processing gas comprises a first precursor delivered at a first rate and etchants delivered at a second rate, sustaining a plasma formed from the first precursor present in the semiconductor processing chamber during at least a first portion of the time period, and depositing the metal containing-layer on at least a portion of a semiconductor structure during the time period until an endpoint thickness is reached. Delivering the processing gas into the semiconductor processing chamber generally includes delivering the first precursor and the etchants during the time period or delivering the first precursor during a first part of the time period and delivering the etchants during a second part of the time period.

### BACKGROUND

### Field

Embodiments of the present disclosure generally relate to a system used in semiconductor device manufacturing. More specifically, embodiments of the present disclosure relate to methods for material deposition in a semiconductor processing system and the semiconductor processing system for depositing the same.

### Description of the Related Art

Thin-film deposition is an important technique utilized in semiconductor device fabrication to create and deposit thin film coatings onto a substrate material. For example, thin-film deposition may be used in the manufacture of electronics like integrated circuits, as well as other products. Thin-film deposition may involve using a chemical vapor deposition (CVD) process or an atomic layer deposition (ALD) process. The deposition of single crystalline metals or metal silicides, such as molybdenum (Mo), molybdenum silicide (MoSi2), titanium (Ti), or titanium silicide (TiSi2), is of particular importance in semiconductor device fabrication. However, temperature and pressure constraints during deposition may limit deposition rates and/or selectivity when using CVD or ALD process.

Accordingly, there is a need in the art for improved deposition processes that help address the problems described above.

### SUMMARY

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

Embodiments provided herein generally include processing systems, and methods for the processing of a substrate in a processing chamber.

Embodiments of the present disclosure are directed to a method of depositing a metal containing-layer in a semiconductor processing chamber. The method generally includes delivering a processing gas into the semiconductor processing chamber during a time period, where the processing gas includes a first precursor delivered at a first rate and etchants delivered at a second rate, sustaining a plasma formed from the first precursor present in the semiconductor processing chamber during at least a first portion of the time period, and depositing the metal containing-layer on at least a portion of a semiconductor structure during the time period until an endpoint thickness is reached.

Embodiments of the present disclosure are directed to a method of depositing a metal containing-layer in a semiconductor processing chamber. The method generally includes delivering a processing gas into the semiconductor processing chamber during a time period, where the processing gas includes a first precursor delivered at a first rate during the time period and etchants delivered at a second rate during the time period, and where the first precursor includes at least one of molybdenum (Mo), titanium (Ti), cobalt (Co), tungsten (W), tantalum (Ta), nickel (Ni), zirconium (Zr), copper (Cu), or silver (Ag), sustaining a plasma formed from the first precursor present in the semiconductor processing chamber during at least a first portion of the time period, and depositing the metal containing-layer on at least a portion of a semiconductor structure during the time period until an endpoint thickness is reached.

Embodiments of the present disclosure provide a semiconductor processing chamber. The semiconductor processing chamber generally includes memory and a controller coupled to the memory, the controller being configured to perform a method of depositing a metal containing-layer in the semiconductor processing chamber. The method generally includes delivering a processing gas into the semiconductor processing chamber during a time period, where the processing gas includes a first precursor delivered at a first rate and etchants delivered at a second rate, sustaining a plasma formed from the first precursor present in the semiconductor processing chamber during at least a first portion of the time period, and depositing the metal containing-layer on at least a portion of a semiconductor structure during the time period until an endpoint thickness is reached.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope and may admit to other equally effective embodiments.

FIG. 1 is a schematic cross-sectional view of an example processing chamber, in which embodiments of the present disclosure may be implemented.

FIG. 2 is a process flow diagram illustrating a method of deposition in a semiconductor processing chamber of a semiconductor processing system, in accordance with certain embodiments of the present disclosure.

FIGS. 3A-3E illustrate schematic side cross-sectional views of a portion of a semiconductor structure during the method of deposition of FIG. 2, according to one or more of the embodiments described herein.

FIG. 4 illustrates a table that displays various ranges associated with the method of FIG. 2, according to one or more of the embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Certain embodiments of the present disclosure are generally directed to techniques and apparatus for selective deposition in a processing chamber of a semiconductor processing system. The selective deposition may include selective deposition of a metal containing-layer on a semiconductor structure (e.g., a substrate) by delivering a processing gas that may include a precursor (e.g., a precursor that includes at least one of at least one of molybdenum (Mo), titanium (Ti), cobalt (Co), tungsten (W), tantalum (Ta), nickel (Ni), zirconium (Zr), copper (Cu), or silver (Ag)) and etchants (e.g., etchants that include at least one of hydrogen chloride (HCl), dichlorine (Cl₂), or a fluorine (F) containing gas) to the semiconductor structure. The etchants may be provided while the precursor is delivered into the processing chamber or after the precursor is delivered. A plasma formed within the processing chamber may be sustained by providing a power within a range (e.g., 0-10,000 watts (W)) during the delivery of the precursor and etchants. In some embodiments, the temperature of the semiconductor structure may be maintained within a temperature range (e.g., 200-1500 degrees Celsius (C)) and the pressure of the processing chamber may be maintained within a pressure range (e.g., 1-500 milliTorr (mTorr)) during the delivery of the precursor and etchants.

The deposited metal containing-layer may include, for example, a single crystalline metal and/or a metal silicide (e.g., molybdenum (Mo), molybdenum silicide (MoSi2), titanium (Ti), or titanium silicide (TiSi2)). The use of the selective deposition described herein may result in high metal containing-layer growth rates (e.g., greater than 100 angstroms (Å)/min), which may not be achievable using thermal atomic layer deposition (ALD) or chemical vapor deposition (CVD).

### Plasma Processing System Examples

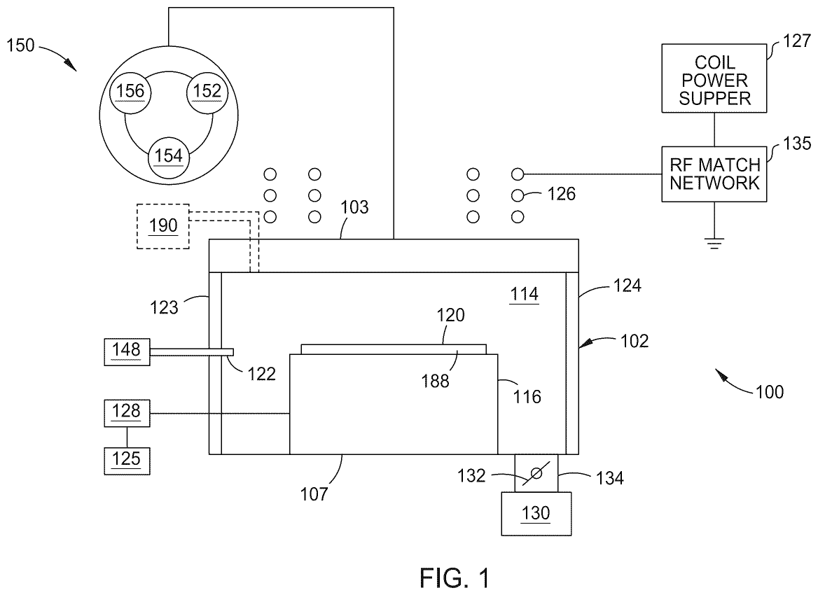

FIG. 1 is a schematic cross-sectional view of an example semiconductor processing chamber 100 (which may be referred to herein as the processing chamber 100) of a semiconductor processing system, in which embodiments of the present disclosure may be implemented. In some embodiments, the processing chamber 100 may be configured to generate a plasma using an inductively coupled plasma (ICP) source (e.g., inductive coil 126) disposed over a processing volume (e.g., interior volume 114) of the processing chamber 100, as illustrated in FIG. 1. In other embodiments, the processing chamber 100 may be configured to form a capacitively-coupled-plasma (CCP) by electrically coupling a radio frequency (RF) source to a lid of the processing chamber 100 (e.g., to ceiling 103), the RF source being configured to deliver an RF signal that maintains a plasma in the interior volume 114 of the processing chamber 100. In still other embodiments, a remote plasma source 190 may be coupled to the processing chamber 100 and may be configured to supply disassociated species to the interior volume 114.

Suitable processing chambers include inductively and capacitive coupled plasma etch chambers such as the SYM3® etch system, available from Applied Materials, Inc., of Santa Clara, California, among others. Other types of processing chambers may be adapted to benefit from the embodiments described herein, including, for example, capacitive coupled parallel plate chambers, and magnetically enhanced ion etch chambers, as well as inductively coupled plasma etch chambers.

The processing chamber 100 may include a chamber body 102 and a ceiling 103 that is energy transparent, i.e., enabling energy to be transmitted therethrough. The chamber body 102 may include sidewalls 123, 124, a ceiling 103, and a chamber bottom 107. An interior volume 114 is defined in the chamber body 102 between the substrate support 116 and the ceiling 103 . . . . The chamber body 102 may be fabricated from a metal, such as anodized aluminum or stainless steel. The ceiling 103 may be mounted on the sidewalls 123, 124 of the chamber body 102. The ceiling 103 may be flat, rectangular, arcuate, conical, dome, or multi-radius shaped. The inductive coil 126 may be disposed over the ceiling 103 of the processing chamber 100, and may be utilized to energize gases within the processing chamber 100 during processing.

A substrate support 116 may be disposed in the processing chamber 100 includes a substrate support surface 188 configured to support a substrate 120 during processing. The substrate support 116 may include an electrostatic chuck, with optionally at least a portion of the substrate support 116 being electrically conductive and capable of serving as a process bias cathode.

Processing gases are introduced into the processing chamber 100 from a process gas source 148 through a gas distributor 122. The gas distributor 122 may be disposed in the ceiling 103 or chamber body 102, above the substrate support 116. Mass flow controllers (not shown) for each processing gas, or alternatively, for mixtures of the processing gas, may be disposed between the gas distributor 122 and the process gas source 148 to regulate the respective flow rates of the process gases into the chamber body 102.

The plasma is formed in the interior volume 114 from the processing gases using a coil power supply 127 which supplies power to the inductive coil 126 to generate an electromagnetic field in the interior volume 114 through a radio frequency (RF) match network 135. The substrate support 116 may include an electrode disposed therein, which is powered by an electrode power supply 125 and generates a capacitive electric field in the processing chamber 100 through a RF match network 128. RF power is applied to the electrode in the substrate support 116 while the chamber body 102 is electrically grounded. The capacitive electric field is transverse to the plane of the substrate support 116, and influences the directionality of charged species more normal to the substrate 120 to provide more vertically oriented anisotropic etching of the substrate 120.

Process gases and etchant byproducts are exhausted from the processing chamber 100 through an exhaust system 130. The exhaust system 130 may be disposed in the chamber bottom 107 of the processing chamber 100 or may be disposed in another portion of the chamber body 102 of the processing chamber 100 for removal of processing gases. A throttle valve 132 is provided in an exhaust port 134 for controlling the pressure in the processing chamber 100.

The controller 150 includes a programmable central processing unit (CPU) 152 and/or one or more processors which are operable with a memory 154 (e.g., non-volatile memory) and support circuits 156. The support circuits 156 are conventionally coupled to the CPU 152 and comprise cache, clock circuits, input/output subsystems, power supplies, and the like, and combinations thereof coupled to the various components of the processing chamber 100, to facilitate control thereof.

The CPU 152 is one of any form of general purpose computer processor used in an industrial setting, such as a programmable logic controller (PLC), for controlling various components and sub-processors of the processing system. The memory 154, coupled to the CPU 152, is non-transitory and is typically one or more of readily available memories such as random access memory (RAM), read only memory (ROM), floppy disk drive, hard disk, or any other form of digital storage, local or remote. The memory 154 stores instructions that when executed by the CPU 152 and/or the one or more processors included in the controller 150 perform processes, such as the method 200 described below, in the processing chamber 100.

Typically, the memory 154 is in the form of a non-transitory computer-readable storage media containing instructions (e.g., non-volatile memory), which when executed by the CPU 152, facilitates the operation of the processing chamber 100. The instructions in the memory 154 are in the form of a program product such as a program that implements the methods of the present disclosure. The program code may conform to any one of a number of different programming languages. In one example, the disclosure may be implemented as a program product stored on computer-readable storage media for use with a computer system. The program(s) of the program product define functions of the embodiments (including the methods described herein).

Illustrative non-transitory computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory devices, e.g., solid state drives (SSD)) on which information may be permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure. In some embodiments, the methods set forth herein, or portions thereof, are performed by one or more application specific integrated circuits (ASICs), field-programmable gate arrays (FPGAs), or other types of hardware implementations. In some other embodiments, the substrate processing and/or handling methods set forth herein are performed by a combination of software routines, ASIC(s), FPGAs and, or, other types of hardware implementations. One or more controllers 150 may be used with one or any combination of the various systems described herein.

### Deposition Examples

In some embodiments, thin-film deposition (e.g., deposition of Mo, Ti, Co, W, Ta, Ni, Zr, Cu, or Ag) may involve using a chemical vapor deposition (CVD) process or an atomic layer deposition (ALD) process to deposit thin film coatings onto a semiconductor structure (e.g., a substrate). The CVD and ALD processes may be performed using a processing chamber (e.g., processing chamber 100) that includes the semiconductor structure has a low temperature to reduce the thermal budget of the CVD or ALD process and to provide a large selectivity window. However, when the semiconductor structure is at a low temperature (e.g., less than or equal to 500° C.), the deposition rate using thermal ALD or CVD processes may be small (e.g., 10 Å/cycle or less). Moreover, the low temperature also reduces the dissociation of etchant chemistry and thus also reduces the etch rate, making the deposition more non-selective. In addition, having low pressure in the processing chamber may be desirable to reduce film defects, roughness, across substrate uniformity, micro-loading, and pattern top to bottom coverage differences. However, the deposition rate tends to drop with lower processing chamber pressure (e.g., less than or equal to 100 mTorr), especially when combined with low substrate temperature (e.g., less than or equal to 500° C.).

Embodiments of the present disclosure are directed to techniques and apparatus for a selective deposition on a semiconductor structure in a processing chamber. The selective deposition may involve use of a plasma to dissociate precursors in a processing chamber while maintaining the temperature of the semiconductor structure within a temperature range (e.g., within 200-1500° C.) and the pressure of the processing chamber within a pressure range (e.g., within 1-500 mTorr) during the delivery of the precursor and etchants. As a result, high growth rates (e.g., greater than 100 Å/min) may be achieved at low semiconductor structure temperatures and low processing chamber pressure. Furthermore, embodiments herein may enable a larger selectivity window to be achieved at low temperature, as the plasma dissociates the etchants, which may suppress and/or etch the nucleation on undesired materials surfaces.

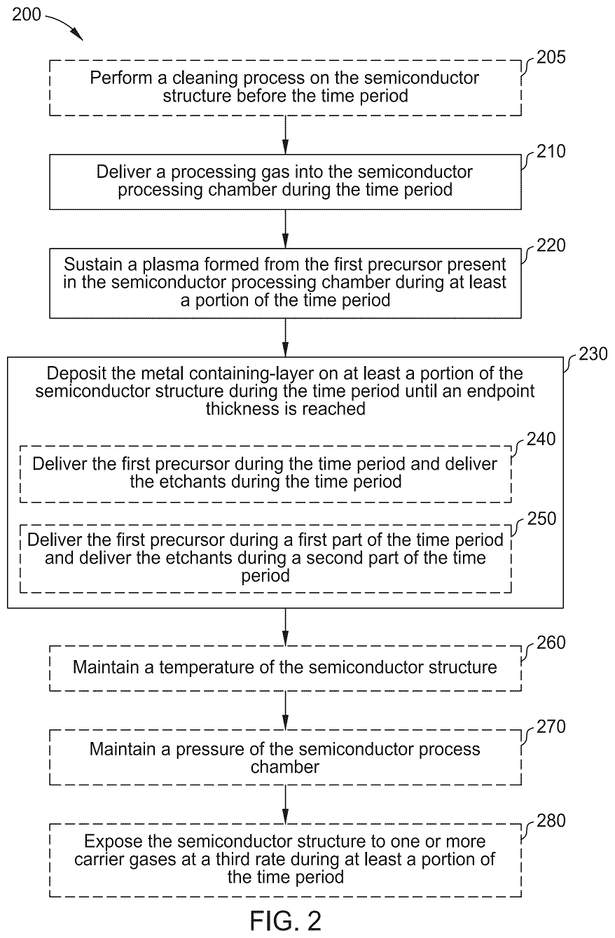

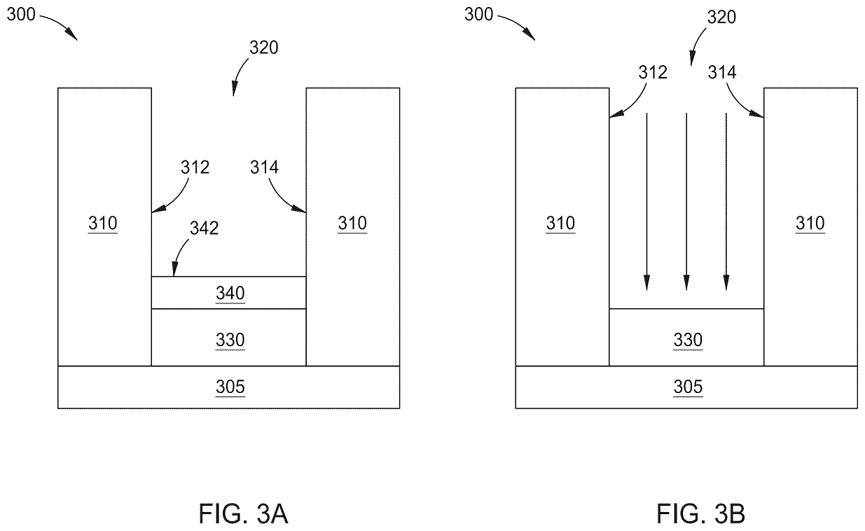

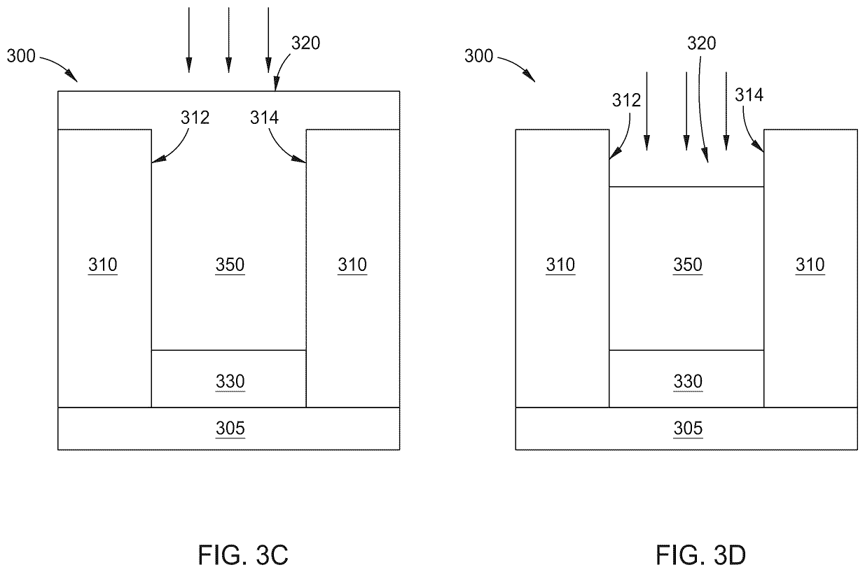

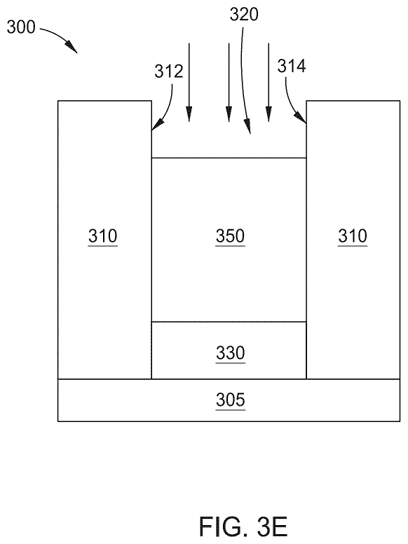

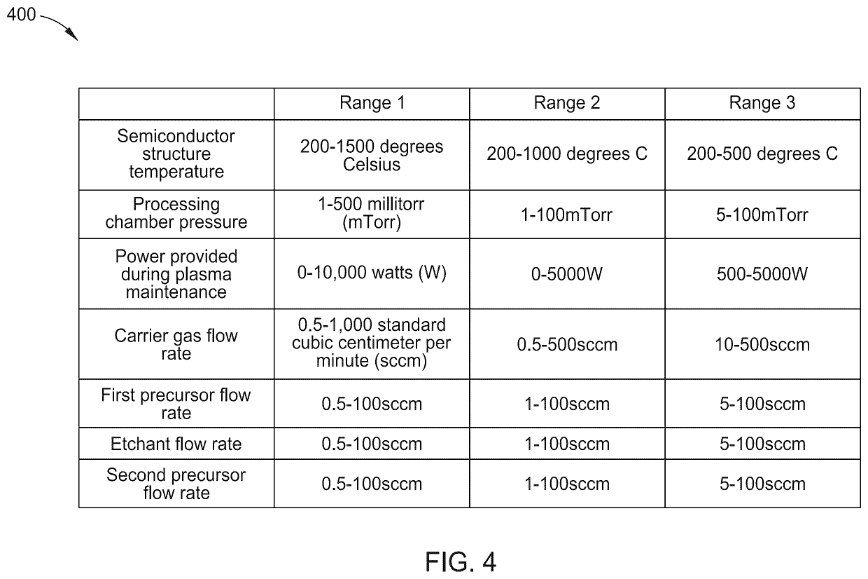

FIG. 2 is a process flow diagram illustrating a method 200 of deposition in a semiconductor processing chamber (e.g., processing chamber 100) of a semiconductor processing system, in accordance with certain embodiments of the present disclosure. FIGS. 3A-3E illustrate schematic side cross-sectional views of a portion of a semiconductor structure 300 (e.g., a semiconductor structure that may be formed on or include a semiconductor wafer or a substrate) during the method of deposition of FIG. 2, according to one or more of the embodiments described herein. FIG. 4 illustrates a table that displays various ranges associated with the method of FIG. 2, according to one or more of the embodiments described herein. Therefore, FIG. 2, FIGS. 3A-3E, and FIG. 4 are herein described together for clarity. It is to be understood that any of the ranges described in the table 400 of FIG. 4 may be combined with any other range described in the table 400 of FIG. 4.

It is assumed that the semiconductor structure 300 includes a dielectric layer 310 previously formed on a substrate 305, a feature 320, a conductive layer 330, and an oxide 340, as illustrated in FIG. 3A. Within the feature 320, a surface 342 of the oxide 340 is exposed, as shown. The feature 320 may be disposed over the conductive layer 330 (e.g., which may be a metal layer), and may include or be implemented as a via, a trench, or an interconnect, or any combination of a via, trench, and interconnect. The dielectric layer 310 may form a first sidewall 312 of the feature 320 and a second sidewall 314 of the feature 320, the second sidewall 314 being parallel to the first sidewall 312, also as illustrated. The method 200 may alternatively be used to deposit other features or even a flat surface.

The term “substrate” as used herein refers to a layer of material that serves as a basis for subsequent processing operations and includes a surface to be cleaned. The substrate may be a silicon based material or any suitable insulating materials or conductive materials as needed. The substrate may include a material such as crystalline silicon (e.g., Si<100> or Si<111>), silicon oxide, plastic, strained silicon, silicon germanium, doped or undoped polysilicon, doped or undoped silicon wafers and patterned or non-patterned wafers, silicon on insulator (SOI), carbon doped silicon oxides, silicon nitride, doped silicon, germanium, gallium arsenide, glass, or sapphire.

The method 200 may optionally include, at operation 205, performing a cleaning process on the semiconductor structure 300 before a time period during which the substrate 305 is processed. In some embodiments, performing the cleaning process on the semiconductor structure 300 may include using a reductive plasma to generate radicals to at least reduce the oxide 340. For example, performing the cleaning process on the semiconductor structure 300 may include exposing the semiconductor structure 300 to at least one of H₂ or HCl to at least reduce the oxide 340 from a surface of the semiconductor structure 300, as illustrated in FIG. 3B. The oxide 340 may include, for example metal oxide, silicon oxide, and/or dielectric surface oxides.

The method 200 includes, at operation 210, delivering a processing gas into the semiconductor processing chamber during the time period. The processing gas includes a first precursor (e.g., a deposition gas) delivered at a first rate and etchants delivered at a second rate. The first rate at which the semiconductor structure 300 may be exposed (e.g., by delivering the first precursor to the processing volume within the processing chamber) to the first precursor may be within 0.5-100 sccm, within 1-100 sccm, or within 5-100 sccm, as described in the row labeled “First precursor flow rate” in the table 400 of FIG. 4.

The first precursor may include at least one of Mo, Ti, Co, W, Ta, Ni, Zr, Cu, or Ag. For example, the first precursor may include at least one of molybdenum (V) chloride (MoCl₅), molybdenum dichloride dioxide (MoCl₂O₂), titanium tetrachloride (TiCl₄), cobalt (II) chloride (CoCl₂), tetramethylethylenediamine (TMEDA), tungsten (VI) fluoride (WF₆), tungsten (V) chloride (WCl₅), tantalum (V) chloride (TaCl₅), Ni(dmamb)2, Ni(hfip)2, Ni(Cp)2, zirconium (IV) chloride (ZrCl₄). tetra-n-butyl orthosilicate (TBOS), copper (I) chloride (CuCl), Ag (fod) (PEt3), or a combination thereof.

The method 200 includes, at operation 220, sustaining a plasma formed from the first precursor present in the semiconductor processing chamber during at least a first portion of the time period. In some embodiments, the plasma may be provided during the entirety of the first time period (e.g., when the method 200 includes operation 240). In other embodiments, the plasma may be provided during a portion of the time period (e.g., when the method includes operation 230). It is to be understood that in some embodiments, either operation 240 or operation 250 may be utilized in the method 200. The plasma may be an ICP, CCP, or a combination of ICP and CCP. The power provided to sustain the plasma may be within 0-10,000 W, within 0-5,000 W, or within 500-5,000 W, as described in the row labeled “Power provided during plasma ignition and maintenance” in the table 400 of FIG. 4. In some embodiments, the plasma may alternatively be formed in a remote plasma source (e.g., remote plasma source 190), such that there are fewer ions and more radicals are provided to the processing volume of the processing chamber). In some cases, a bias power (e.g., direct current (DC) power or RF power, ranging from 0 to 10,000 W) may be applied to the processing chamber to enhance the ion bombardment of the surface of the semiconductor structure 300.

The method 200 includes, at operation 230, depositing a metal containing-layer 350 on at least a portion of the semiconductor structure 300 during the time period until an endpoint thickness is reached, as illustrated in FIGS. 3C and 3E. In other words, delivering the processing gas at operation 210 and sustaining the plasma at operation 220 may expose the semiconductor structure 300 to the first precursor and form (e.g., grow) the metal containing-layer 350. The endpoint thickness may be equal to the height of the feature 320 (e.g., the metal containing-layer 350 may fill the feature 320 to the height of the dielectric layer 310), a portion of the height of the feature 320 (e.g., as illustrated in FIGS. 3D and 3E), or any height in between. FIG. 3C illustrates the semiconductor structure 300 during operation 230 without operation 240, which is described below. As a result, excess and undesirable portions of the metal containing-layer 350 are formed, for example, on the dielectric layer 310, and operation 250 may be performed to at least reduce (or remove) the excess metal containing-layer 350. FIG. 3E illustrates the semiconductor structure 300 during operation 230 and operation 240, which is described below. As a result, the excess metal containing-layer 350 illustrated in FIG. 3C is not formed as a result of the concurrent deposition and etch. The metal containing-layer 350 may include crystalline metal and/or metal silicide. For example, the metal containing-layer 350 may include at least one of Mo, molybdenum silicide (MoSi2), Ti, or titanium silicide (TiSi2). In another example, the metal containing-layer 350 may include at least one of Mo, MoSi2, Ti, TiSi2, Co, cobalt silicide (CoSi2), W, tungsten silicide (WSi2), Ta, tantalum silicide (TaSi2), Ni, nickel silicide (NiSi2), Zr, zirconium silicide (ZrSi2), Cu, copper silicide (Cu5Si), or Ag.

In some embodiments, the operation 230 of the method 200 may include operation 240, which includes delivering the first precursor at the first rate during the time period and delivering the etchants at the second rate during the time period, as illustrated in FIG. 3E. In this manner, the etchants may be delivered to the semiconductor structure 300 while the semiconductor structure 300 is exposed to the first precursor and during formation of the metal containing-layer 350. That is, the metal containing-layer 350 may be formed on the conductive layer 330 (e.g., in the feature 320 and using the first precursor from operation 210) while any undesirable metal containing-layer 350 formed on the dielectric layer 310 (e.g., as illustrated in FIG. 3C) is at least reduced (e.g., using the etchants from operation 210), resulting in effectively a simultaneous deposition and etch (e.g., “co-flow”) as both the first precursor and the etchants are flowing into the processing chamber and delivered to the semiconductor structure 300 at the same time. The metal containing-layer 350 formed in the feature 320 may at least partially fill the feature 320, as illustrated in FIG. 3E.

In some embodiments, the operation 230 of the method 200 may include operation 250, which includes delivering the first precursor at the first rate during a first part of the time period and delivering the etchants at the second rate during a second part of the time period, as illustrated in FIG. 3D. In this manner, the etchants may be delivered to the semiconductor structure 300 after the semiconductor structure 300 is exposed to the first precursor and the metal containing-layer 350 is formed. That is, the metal containing-layer 350 may be formed on the conductive layer 330 (e.g., in the feature 320) and the dielectric layer 310 (e.g., using the first precursor from operation 210) as illustrated in FIG. 3C, and subsequently the excess and undesirable portion of the metal containing-layer 350 formed, for example, on the dielectric layer 310 is at least reduced (e.g., using the etchants from operation 210) as illustrated in FIG. 3D, resulting in effectively consecutive deposition and etch operations. The metal containing-layer 350 formed in the feature 320 may at least partially fill the feature 320, as illustrated in FIG. 3D. In some embodiments, the method 200 may be cyclical. For example, the deposition (e.g., during the first part of the time period) and the etching (e.g., during the second part of the time period) may be repeated any number of times to produce the desired semiconductor structure 300. In some embodiments, the first part of the time period and the second part of the time period do not overlap. In other embodiments, the first part of the time period and the second part of the time period at least partially overlap. As a result of the lower etch rate of the metal containing-layer 350 in the feature 320 (e.g., due to the higher quality of metal containing-layer 350 in the feature 320) than the metal containing-layer 350 disposed on the dielectric layer 310 (e.g., due to the lower quality of metal containing-layer 350 disposed on the dielectric layer 310), such that the desired selectivity during operations 230 and 250 may be achieved.

In some embodiments, the first precursor from operation 230 (e.g., and/or the second precursor described below, if present) may be purged from the processing chamber before the second part of the time period (e.g., the delivery of the etchants). In other embodiments, the first precursor from operation 210 (e.g., and/or the second precursor, if present) may remain in the processing chamber during the second part of the time period (e.g., the delivery of the etchants).

The third rate at which the semiconductor structure 300 may be exposed to the etchants may be within 0.5-100 sccm, within 1-100 sccm, or within 5-100 sccm, as described in the row labeled “Etchant flow rate” in the table 400 of FIG. 4.

The etchants delivered at operation 240 and operation 250 may include at least one of hydrogen chloride (HCl), dichlorine (Cl₂), or a fluorine (F) containing gas. For example, the etchants may include one or more of carbon tetrafluoride (CF₄), trifluoromethane (CHF₃), difluoromethane (CH₂F₂), methyl fluoride (CH₃F), or hexafluorodisilane (Si₂F₆).

The method 200 may optionally include, at operation 260, maintaining a temperature of the semiconductor structure 300 in the processing chamber within a temperature range during the time period. The temperature range that the temperature of the semiconductor structure 300 may be maintained at may be within 200-1500° C., within 200-1000° C., or within 200-500° C., as described in the row labeled “Semiconductor structure temperature” in the table 400 of FIG. 4. The temperature of the semiconductor structure 300 may be maintained with the temperature range during the entirety of the time period, or a portion of the time period.

The method 200 may optionally include, at operation 270, maintaining a pressure of the processing chamber (e.g., a pressure of the processing volume within the processing chamber) within a pressure range during the time period. The pressure range that the pressure of the processing chamber may be maintained at may be within 1-500 mTorr, within 1-100 mTorr, or within 5-100 mTorr, as described in the row labeled “Processing chamber pressure” in the table 400 of FIG. 4. The pressure of the processing chamber may be maintained with the pressure range during the entirety of the time period, or a portion of the time period. It is to be understood that any of the pressure ranges described herein may be combined with any of the temperature ranges described herein.

The method 200 may optionally include, at operation 280, exposing the semiconductor structure 300 in the processing chamber to one or more carrier gases at a first rate during at least a second portion of the time period. The one or more carrier gases may include at least one of argon (Ar), hydrogen (H₂), helium (He), neon (Ne), krypton (Kr), or xenon (Xe). The first rate at which the semiconductor structure 300 may be exposed to the one or more carrier gases (e.g., by delivering the one or more carrier gases to the processing volume within the processing chamber) may be within 0.5-1,000 standard cubic centimeter per minute (sccm), within 0.5-500 sccm, or within 10-500 sccm, as described in the row labeled “Carrier gas flow rate” in the table 400 of FIG. 4.

In some embodiments, the carrier gases may be kept in the processing chamber during the entirety of the time period, such as, for example, during operations 210, 220, 230, and 240 or 250. In other embodiments, the carrier gases may be eliminated before operation 210. In this manner, the dissociation of the etchants may be improved, resulting in an increased release of Cl or F which enhances the etch reaction and improves the etch selectivity of the method 200.

According to certain embodiments, the method 200 may further include exposing the semiconductor structure 300 to a second precursor (e.g., a Si source precursor) at a third rate during the time period. The second precursor may be utilized in cases where it is desirable to form metal silicides on the semiconductor structure 300 as at least part of the metal containing-layer 350. The second precursor may include one or more of Si source precursors such tetrasilane (Si₄H₁₀), trisilane (Si₃H₈), disilane (Si₂H₆), silane (SiH₄), dichlorosilane (SiH₂Cl₂), trichlorosilane (SiHCl₃), silicon tetrachloride (SiCl₄), or a combination thereof. The rate at which the semiconductor structure 300 may be exposed to the second precursor may be within 0.5-100 sccm, within 1-100 sccm, or within 5-100 sccm, as described in the row labeled “Second precursor flow rate” in the table 400 of FIG. 4.

### Additional Considerations

In the above description, details are set forth by way of example to facilitate an understanding of the disclosed subject matter. It should be apparent to a person of ordinary skill in the field, however, that the disclosed implementations are exemplary and not exhaustive of all possible implementations. Thus, it should be understood that reference to the described examples is not intended to limit the scope of the disclosure. Any alterations and further modifications to the described devices, instruments, methods, and any further application of the principles of the present disclosure are fully contemplated as would normally occur to one skilled in the art to which the disclosure relates. In particular, it is fully contemplated that the features, components, and/or steps described with respect to one implementation may be combined with the features, components, and/or steps described with respect to other implementations of the present disclosure. As used herein, the term “about” may refer to a +/−10% variation from the nominal value. It is to be understood that such a variation can be included in any value provided herein.

As used herein, “a processor,” “at least one processor” or “one or more processors” generally refers to a single processor configured to perform one or multiple operations or multiple processors configured to collectively perform one or more operations. In the case of multiple processors, performance of the one or more operations could be divided amongst different processors, though one processor may perform multiple operations, and multiple processors could collectively perform a single operation. Similarly, “a memory,” “at least one memory” or “one or more memories” generally refers to a single memory configured to store data and/or instructions, multiple memories configured to collectively store data and/or instructions.

As used herein, a phrase referring to “at least one of” or “one or more of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

As used herein, a phrase describing something being within a range between two values or within a range from one value to another value includes the values of the endpoints in the range. In other words, any phrase describing something being within range used herein is inclusive of the endpoints of the range. As an example, “within a range from 1 and 10” or “within a range between 1 and 10” is intended to cover a range of values from 1 to 10 that includes both 1 and 10.

While the foregoing is directed to embodiments of the present disclosure, other and further embodiments of the disclosure may be devised without departing from the basic scope thereof, and the scope thereof is determined by the claims that follow.

What is claimed is:

1. A method of depositing a metal containing-layer in a semiconductor processing chamber, the method comprising:
delivering a processing gas into the semiconductor processing chamber during a time period, wherein the processing gas comprises a first precursor delivered at a first rate and etchants delivered at a second rate;
sustaining a plasma formed from the first precursor present in the semiconductor processing chamber during at least a first portion of the time period; and
depositing the metal containing-layer on at least a portion of a semiconductor structure during the time period until an endpoint thickness is reached.

2. The method of claim 1, wherein delivering the processing gas into the semiconductor processing chamber comprises delivering the first precursor at the first rate during the time period and delivering the etchants at the second rate during the time period.

3. The method of claim 1, wherein delivering the processing gas into the semiconductor processing chamber comprises delivering the first precursor at the first rate during a first part of the time period and delivering the etchants at the second rate during a second part of the time period.

4. The method of claim 1, wherein the etchants comprise at least one of hydrogen chloride (HCl), dichlorine (Cl₂), or a fluorine (F) containing gas.

5. The method of claim 1, wherein the first precursor comprises at least one of molybdenum (Mo), titanium (Ti), cobalt (Co), tungsten (W), tantalum (Ta), nickel (Ni), zirconium (Zr), copper (Cu), or silver (Ag).

6. The method of claim 1, further comprising:
maintaining a temperature of the semiconductor structure within a first temperature range from 200 to 1500 C during the time period; and
maintaining a pressure of the semiconductor processing chamber within a first pressure range from 1 to 500 mTorr during the time period.

7. The method of claim 6, wherein:
the temperature of the semiconductor structure is maintained within a second temperature range from 200 to 500 C; and
the pressure of the semiconductor processing chamber is maintained within a second pressure range from 5 to 100 mTorr.

8. The method of claim 1, wherein:
the first rate is between 0.5 and 100 standard cubic centimeter per minute (sccm); and
the second rate is between 0.5 and 100 sccm.

9. The method of claim 1, further comprising performing a cleaning process on the semiconductor structure before the time period, the cleaning process comprising exposing the semiconductor structure to at least one of hydrogen (H₂) or hydrogen chloride (HCl) to at least reduce an oxide from a surface of the semiconductor structure.

10. The method of claim 1, further comprising exposing the semiconductor structure to one or more carrier gases at a third rate during at least a second portion of the time period, wherein the one or more carrier gases comprises at least one of argon (Ar), hydrogen (H₂), helium (He), neon (Ne), krypton (Kr), or xenon (Xe).

11. The method of claim 1, wherein the processing gas further comprises a second precursor delivered at a third rate during the time period.

12. The method of claim 1, wherein the semiconductor structure comprises:
a conductive layer;
a feature disposed over the conductive layer; and
a dielectric layer forming a first sidewall of the feature and a second sidewall of the feature, the second sidewall being parallel to the first sidewall, wherein the metal containing-layer comprises at least one of a single crystalline metal or a metal silicide that comprises at least one of molybdenum (Mo), molybdenum silicide (MoSi2), titanium (Ti), or titanium silicide (TiSi2).

13. A method of depositing a metal containing-layer in a semiconductor processing chamber, the method comprising:
delivering a processing gas into the semiconductor processing chamber during a time period, wherein the processing gas comprises a first precursor delivered at a first rate during the time period and etchants delivered at a second rate during the time period, and wherein the first precursor comprises at least one of molybdenum (Mo), titanium (Ti), cobalt (Co), tungsten (W), tantalum (Ta), nickel (Ni), zirconium (Zr), copper (Cu), or silver (Ag);
sustaining a plasma formed from the first precursor present in the semiconductor processing chamber during at least a first portion of the time period; and
depositing the metal containing-layer on at least a portion of a semiconductor structure during the time period until an endpoint thickness is reached.

14. The method of claim 13, wherein the etchants comprise at least one of hydrogen chloride (HCl), dichlorine (Cl₂), or a fluorine (F) containing gas.

15. The method of claim 13, further comprising:
maintaining a temperature of the semiconductor structure within a first temperature range from 200 to 1500 C during the time period; and
maintaining a pressure of the semiconductor processing chamber within a first pressure range from 1 to 500 mTorr during the time period.

16. The method of claim 13, wherein:
the first rate is between 0.5 and 100 standard cubic centimeter per minute (sccm); and
the second rate is between 0.5 and 100 sccm.

17. A semiconductor processing chamber comprising:
memory; and
a controller coupled to the memory, the controller being configured to perform a method of depositing a metal containing-layer in the semiconductor processing chamber, the method comprising:
delivering a processing gas into the semiconductor processing chamber during a time period, wherein the processing gas comprises a first precursor delivered at a first rate and etchants delivered at a second rate;
sustaining a plasma formed from the first precursor present in the semiconductor processing chamber during at least a first portion of the time period; and
depositing the metal containing-layer on at least a portion of a semiconductor structure during the time period until an endpoint thickness is reached.

18. The semiconductor processing chamber of claim 17, wherein delivering the processing gas into the semiconductor processing chamber comprises delivering the first precursor at the first rate during the time period and delivering the etchants at the second rate during the time period, and wherein the etchants comprise at least one of hydrogen chloride (HCl), dichlorine (Cl₂), or a fluorine (F) containing gas.

19. The semiconductor processing chamber of claim 17, wherein delivering the processing gas into the semiconductor processing chamber comprises delivering the first precursor at the first rate during a first part of the time period and delivering the etchants at the second rate during a second part of the time period, and wherein the etchants comprise at least one of hydrogen chloride (HCl), dichlorine (Cl₂), or a fluorine (F) containing gas.

20. The semiconductor processing chamber of claim 17, wherein the first precursor comprises at least one of molybdenum (Mo), titanium (Ti), cobalt (Co), tungsten (W), tantalum (Ta), nickel (Ni), zirconium (Zr), copper (Cu), or silver (Ag).
